(19) United States
(12) Patent Application Publication
(10) Pub. No.: US 2013/0240974 A1
(43) Pub. Date: Sep. 19, 2013

(54) SEMICONDUCTOR DEVICE AND METHOD OF MANUFACTURING THE SAME

(71) Applicant: KABUSHIKI KAISHA TOSHIBA, Tokyo (JP)

(72) Inventor: Kenta YAMADA, Mie-ken (JP)

(73) Assignee: KABUSHIKI KAISHA TOSHIBA, Tokyo (JP)

(21) Appl. No.: 13/794,444

(22) Filed: Mar. 11, 2013

(30) Foreign Application Priority Data
Mar. 14, 2012 (JP) 2012-057219

(51) Int. Cl. H01L 27/115

(52) U.S. Cl. CPC H01L 27/1157
USPC 257/321; 438/258

(57) ABSTRACT

A semiconductor device has a semiconductor substrate, a pair of select gate transistors provided on a first region of the semiconductor substrate, a plurality of memory cell transistors provided on a second region provided between the pair of select gate transistors on the semiconductor substrate, a gate electrode of each of the memory cell transistors, the gate electrode provided on the second region via a first insulating film, and including a charge storage layer, an intermediate insulating film, and a control gate electrode film stacked therein, a groove exposed a sidewall of the semiconductor substrate on the first region; and a gate electrode of each of the select gate transistors, the gate electrode including the control gate electrode film formed on the sidewall via a second insulating film.

### CROSS-REFERENCE TO RELATED APPLICATION

This application is based upon and claims the benefit of priority from the prior Japanese Patent Application No. 2012-057219, filed Mar. 14, 2012, the entire contents of which are incorporated herein by reference.

### FIELD

Embodiments of the invention relate to a semiconductor device, and a method of manufacturing a semiconductor device.

### BACKGROUND

NAND type nonvolatile memory devices of various structures are developed, which include NAND type nonvolatile memory devices of a conventional structure and a flat cell structure, for example. Currently, for advanced miniaturization, the limit of the miniaturization heavily depends on the aspect of processing. The NAND type nonvolatile memory device of the conventional structure can achieve a high coupling ratio, however, the use of the etch back of an element isolation insulating film (an etch back process) causes increased variations of the process. The NAND type nonvolatile memory device of the flat cell structure can realize the minimum aspect of processing, and can omit the etch back process which is included in the conventional structure and has large variations. Accordingly, for further advanced miniaturization, attention is given to the NAND type nonvolatile memory device of the flat cell structure.

However, for lowering the aspect ratio of processing, the NAND type nonvolatile memory device of the flat cell structure is structured such that a thin charge storage layer (trap film, floating gate electrode film) is formed, and this charge storage layer is sandwiched between a tunnel insulating film and an inter-electrode insulating film. Accordingly, when a contact is processed in the charge storage layer, the contact may penetrate beyond the charge storage layer due to over processing, resulting in damage to the tunnel insulating film.

Therefore, examples of a method of forming a select gate for the NAND type nonvolatile memory device of the flat cell structure include a method in which a select gate is formed separately from a memory cell, and a method in which three layers of a tunnel insulating film, a trap film as the charge storage layer, and an inter-electrode insulating film are used as a gate insulating film with a trap film being sandwiched therebetween. The former method increases a manufacturing cost. The latter method increases variations of a threshold value due to influence of electric charges in the trap film, and thus has difficulty in controlling the threshold value of the select gate, because of the three-layer structure of the gate insulating film in which the trap film is sandwiched.

### DESCRIPTION OF THE DRAWINGS

FIG. 1 is an equivalent circuit diagram showing a part of a memory cell array of an NAND type flash memory device according to a first embodiment;

FIG. 2 is an example of an schematic plan view showing a part of a layout pattern of a part of a memory cell region;

FIG. 3A is an example of a schematic cross-sectional view taken along a A-A line in FIG. 2;

FIG. 3B is an example of a schematic cross-sectional view taken along a B-B line in FIG. 2;

FIG. 3C is an example of a schematic cross-sectional view taken along a C-C line in FIG. 2;

FIGS. 4A to 11A are examples of cross-sectional views taken along the A-A in FIG. 2 during a manufacturing process;

FIGS. 4B to FIG. 11B are examples of cross-sectional views taken along the B-B in FIG. 2 during the manufacturing process;

FIGS. 4C to FIG. 11C are examples of cross-sectional views taken along the C-C in FIG. 2 during the manufacturing process;

FIGS. 12A to C are examples of cross-sectional views showing a second embodiment, and corresponding to FIGS. 9A to C, respectively;

FIGS. 13A to C are examples of cross-sectional views corresponding to FIGS. 10A to C, respectively;

FIGS. 14A to C are examples of cross-sectional views corresponding to FIGS. 11A to C, respectively;

FIGS. 15A to C are examples of cross-sectional views showing a third embodiment, and corresponding to FIGS. 9A to C, respectively;

FIGS. 16A to C are examples of cross-sectional views corresponding to FIGS. 10A to C, respectively;

FIGS. 17A to C are examples of cross-sectional views corresponding to FIGS. 11A to C, respectively;

FIGS. 18A to C are examples of cross-sectional views showing a fourth embodiment, and showing steps executed after steps of FIGS. 8A to C, respectively;

FIGS. 19A to C are examples of cross-sectional views corresponding to FIGS. 9A to C, respectively;

FIGS. 20A to C are examples of cross-sectional views corresponding to FIGS. 10A to C, respectively;

FIGS. 21A to C are examples of cross-sectional views corresponding to FIGS. 11A to C, respectively;

FIGS. 22A to C are examples of cross-sectional views showing a fifth embodiment, and showing steps executed after the steps of FIGS. 8A to C, respectively;

FIGS. 23A to C are examples of cross-sectional views corresponding to FIGS. 9A to C, respectively;

FIGS. 24A to C are examples of cross-sectional views corresponding to FIGS. 10A to C, respectively; and

FIGS. 25A to C are examples of cross-sectional views corresponding to FIGS. 11A to C, respectively.

### DETAILED DESCRIPTION

A example of a semiconductor device of the present disclosure is one that has a semiconductor substrate, a pair of select gate transistors provided on a first region of the semiconductor substrate, a plurality of memory cell transistors provided on a second region provided between the pair of select gate transistors on the semiconductor substrate, a gate electrode of each of the memory cell transistors, the gate electrode provided on the second region via a first insulating film, and including a charge storage layer, an intermediate insulating film, and a control gate electrode film stacked therein, a groove exposed a sidewall of the semiconductor substrate on the first region; and a gate electrode of each of the select gate transistors, the gate electrode including the control gate electrode film formed on the sidewall via a second insulating film.

A example of a method of manufacturing a semiconductor device of the present disclosure is one that has forming a first insulating film on a semiconductor substrate, forming a charge storage layer on the first insulating film, forming an element isolation groove by processing the charge storage layer, the first insulating film, and the semiconductor substrate, embedding an element isolation insulating film into the element isolation groove and planarizing the element isolation insulating film, exposing a sidewall of the semiconductor substrate by etching back the semiconductor substrate in a formation region of a select gate transistor while the element isolation insulating film and the charge storage layer in a formation region of a memory cell transistor are masked, doping impurities into an upper surface portion of the semiconductor substrate in the formation region of the select gate transistor, forming an insulating film on the sidewall of the semiconductor substrate, forming a control gate electrode film on the insulating film; and processing a gate electrode of the select gate transistor and a gate electrode of the memory cell transistor.

Hereinafter, a plurality of embodiments will be described with reference to the drawings. In the embodiments, substantially the same constituent portions are denoted by the same reference numerals, and the explanations thereof are omitted. It should be noted that the drawings are schematic, and the relations of the thicknesses and the plane dimensions, the ratios of the thicknesses of layers, and the like differ from actual ones.

### First Embodiment

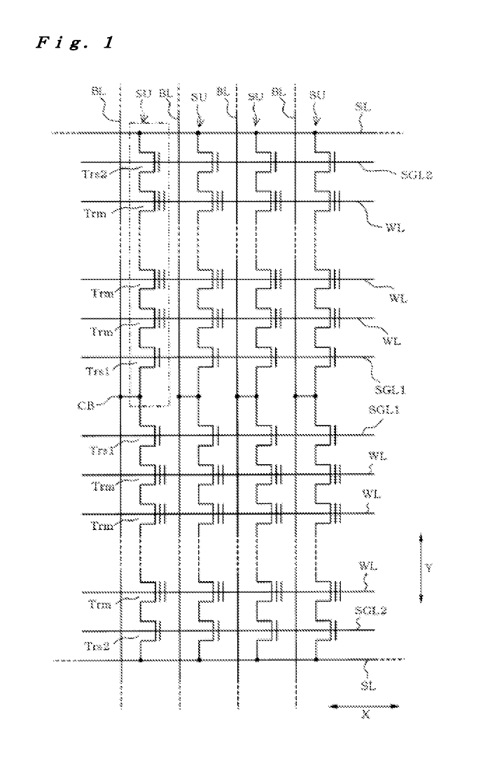

Firstly, FIG. 1 is an equivalent circuit diagram showing a part of a memory cell array of an NAND type flash memory device according to a first embodiment. As shown in FIG. 1, in the memory cell array of the NAND type flash memory device, NAND cell units SU are formed in a matrix. Each of the NAND cell units SU includes two select gate transistors Trs1, Trs2, and a plurality of (for example, 64) memory cell transistors Trm connected in series between the select gate transistors Trs1, Trs2. In each NAND cell unit SU, the plurality of memory cell transistors Trm are formed such that the adjacent memory cell transistors Trm share source/drain regions.

The memory cell transistors Trm aligned in an X direction (corresponding to a word line direction and a gate width direction) in FIG. 1 are connected to a common word line WL. In addition, the select gate transistors Trs1 aligned in the X direction in FIG. 1 are connected to a common select gate line SGL1. Moreover, the select gate transistors Trs2 aligned in the X direction in FIG. 1 are connected to a common select gate line SGL2. A bit line contact CB is connected to a drain region of the select gate transistor Trs1. The bit line contact CB is connected to a bit line BL extending in a Y direction (corresponding to a gate length direction and a bit line direction) orthogonal to the X direction in FIG. 1. In addition, the select gate transistor Trs2 is connected to a source line SL extending in the X direction via a source region in FIG. 1.

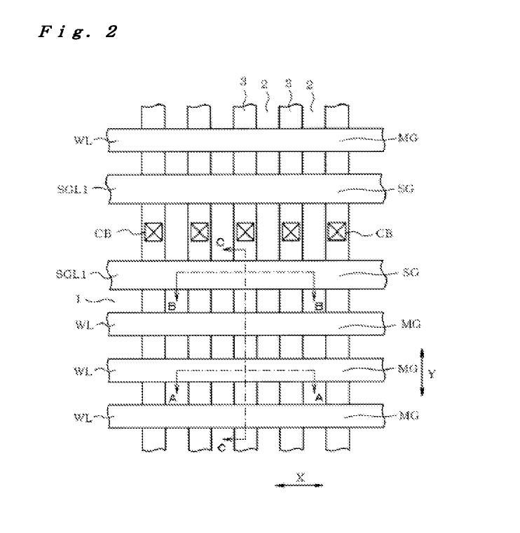

FIG. 2 is a plan view showing a layout pattern of a part of a memory cell region and a drawing-out region of a word line. Firstly, on a silicon substrate 1 serving as a semiconductor substrate in the memory cell region, a plurality of STIs (shallow trench isolations) 2 are formed at a predetermined interval in the X direction in FIG. 2, each of which extends along the Y direction in FIG. 2 and serves as an element isolation region. With the STIs, element regions 3 extending along the Y direction in FIG. 2 are formed separately in the X direction in FIG. 2. The plurality of word lines WL for the memory cell transistors are formed at a predetermined interval in the Y direction in FIG. 2 in such a manner as to extend along the direction (the X direction in FIG. 2) orthogonal to the element regions 3.

Moreover, the pair of select gate lines SGL1 for the select gate transistors are formed in such a manner as to extend in the X direction in FIG. 2. Each bit line contact CB is formed in each of the element regions 3 between the pair of select gate lines SGL1. A gate electrode MG of the memory cell transistor is formed on an intersection of the element region 3 with the word line WL, whereas a gate electrode SG of the select gate transistor is formed on an intersection of the element region 3 with the select gate line SGL1.

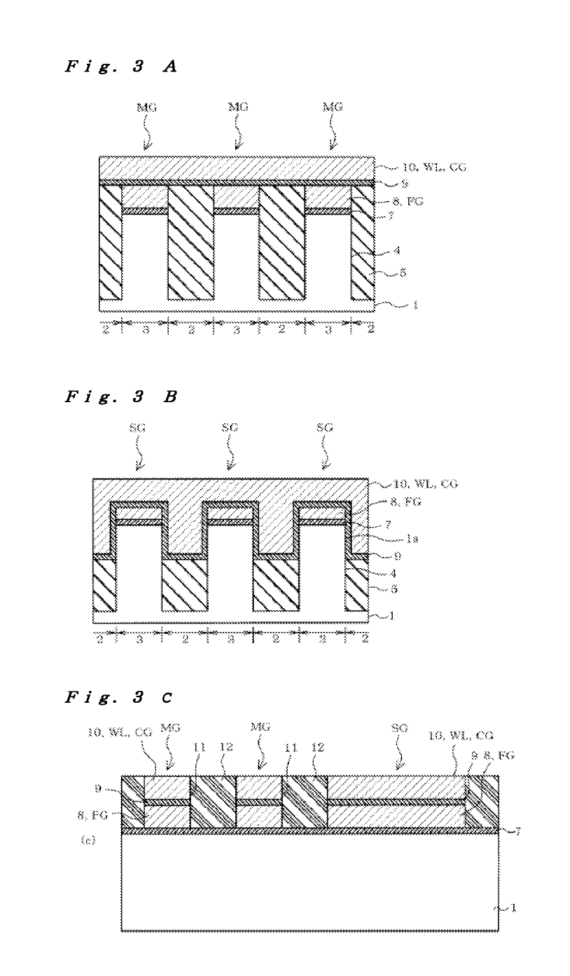

Next, the structure of the gate electrode in the memory cell region according to the embodiment will be described with reference to FIGS. 3A to 3C. FIG. 3A is an example of a view schematically showing a cross section along an A-A line (the word line direction and the X direction) in FIG. 2, FIG. 3B is an example of a view schematically showing a cross section along a B-B line (the word line direction and the X direction) in FIG. 2, and FIG. 3C is an example of a view schematically showing a cross section along a C-C line (the bit line direction and the Y direction) in FIG. 2.

As shown in FIGS. 3A, B, and C, on the upper portion of the silicon substrate 1 of a p-type, a plurality of element isolation grooves 4 are formed in such a manner as to be apart from each other in the X direction. These element isolation grooves 4 separate the element regions 3 in the X direction in FIG. 2. An element isolation insulating film 5 is formed in the element isolation groove 4, and functions as the element isolation region (STI) 2.

The gate electrode MG of the memory cell transistor is provided on a gate insulating film (a first insulating film and a tunnel insulating film) 7 formed on the silicon substrate 1. The source/drain regions are formed at both sides of the gate electrode MG on the upper surface portion of the silicon substrate 1. The gate electrode MG includes a floating gate electrode film FG to be a charge storage layer, an inter-electrode insulating film (intermediate insulating film) 9 formed on the floating gate electrode film FG, and a control gate electrode film CG formed on the inter-electrode insulating film 9. In this configuration, the memory cell transistor has what is called a flat cell structure.

As shown in FIG. 3B, the element isolation insulating film 5 in a formation region (a first region) of the select gate transistor is etched back in such a manner as to expose a sidewall 1a of the silicon substrate 1. The gate electrode SG of the select gate transistor is provided on the inter-electrode insulating film (the second insulating film and the gate insulating film) 9 formed on the sidewall 1a of the silicon substrate 1. Source/drain regions having a (Lightly Doped Drain) structure or a DDD (Double Diffused Drain) structure are formed on a region between the two gate electrodes SG on the upper surface portion of the silicon substrate 1. The gate electrode SG includes the control gate electrode film CG formed on the inter-electrode insulating film 9. In this configuration, the select gate transistor has the inter-electrode insulating film 9 as a gate insulating film formed on the sidewall 1a of the silicon substrate 1, and includes a channel on an upper surface portion of the sidewall 1a of the silicon substrate 1. In addition, on the upper surface of the silicon substrate 1, the gate insulating film (tunnel insulating film) 7 and the floating gate electrode film (charge storage layer) FG are stacked. The inter-electrode insulating film 9 and an inter-memory cell insulating film 12 described later cover the side surfaces of the gate insulating film 7, and the side surfaces and the upper surface of the floating gate electrode film FG. In this configuration, electrons trapped in the floating gate electrode film FG raise a threshold value of the select gate transistor. Note that, the film thickness of the floating gate electrode film FG in the formation region of the select gate transistor is thinner than the film thickness of the floating gate electrode film FG in a formation region of the memory cell transistor.

The gate insulating film 7 is formed on the silicon substrate 1 (element region 3). As for the gate insulating film 7, used is a silicon oxide film, for example. As for the floating gate electrode film FG, used is a polycrystalline silicon layer (conductive layer) 8 with which impurities such as phosphorus are doped, a silicon nitride film (insulating film), a hafnium oxide (insulating film), or a combination thereof, for example. The inter-electrode insulating film 9 is formed along the upper surface of the element isolation insulating film 5 and the upper surface of the floating gate electrode film FG in the formation region (second region) of the memory cell transistor, and functions as an interpoly insulating film, a conductive interlayer insulating film, and an inter-electrode insulating film. In addition, the inter-electrode insulating film 9 is formed along the upper surface of the element isolation insulating film 5, the sidewall 1a of the silicon substrate 1, the side surfaces of the gate insulating film 7, and the side surfaces and the upper surface of the floating gate electrode film FG in the formation region of the select gate transistor (first region), and functions as a gate insulating film (second insulating film).

As for the inter-electrode insulating film 9, used is, for example, a film having a stacked structure of silicon oxide film/silicon nitride film/silicon oxide film (each film thickness in a range from 3 nm to 10 nm, for example), which is called an ONO film. Note that an NONON film or an NONO film, for example, maybe used as the inter-electrode insulating film 9.

The control gate electrode film CG is provided with a conductive layer 10 which functions as the word line WL for the memory cell transistor. The conductive layer 10 has a stacked structure of a polycrystalline silicon layer with which impurities such as phosphorus are doped, a silicide layer which is formed directly over the polycrystalline silicon layer and is silicided by any metal among tungsten (W), cobalt (Co), and nickel (Ni). Note that, a silicide layer (in other words, silicide layer only) or any metal layer among tungsten (W), copper (Cu), and the like (in other words, metal layer only) may be used for the entire conductive layer 10.

As shown in FIG. 3C, the gate electrodes MG of the memory cell transistors are arranged in parallel in the Y direction, and each of the gate electrodes MG is electrically isolated from one another by an electrode isolation groove 11. In the groove 11, the inter-memory cell insulating film 12 is formed. As for the inter-memory cell insulating film 12, used is, for example, a silicon oxide film using TEOS (tetraethyl orthosilicate) or a low-dielectric constant insulating film.

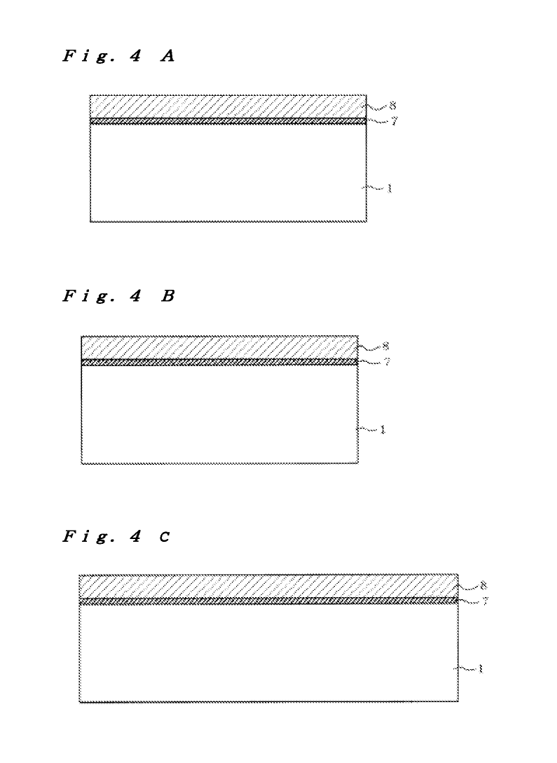

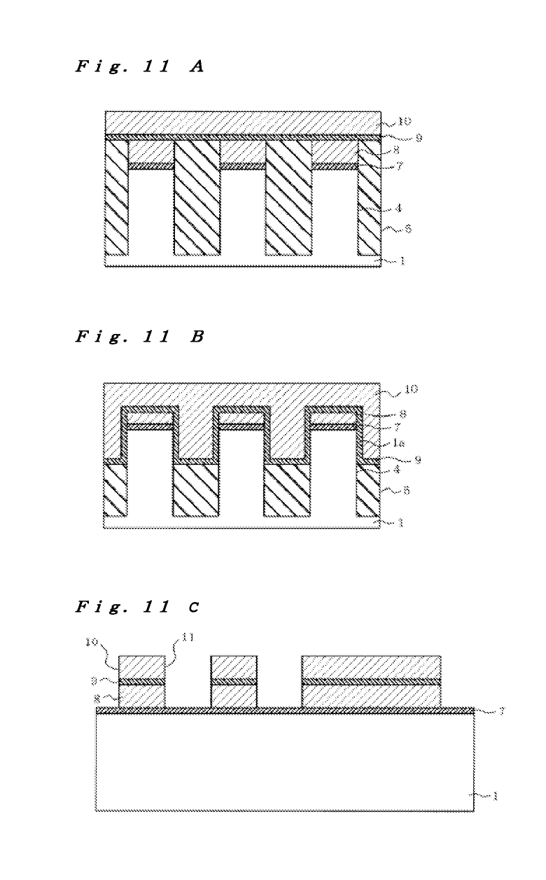

Next, an example of a method of manufacturing an NAND type flash memory device according to the embodiment will be described with reference to step cross-sectional views shown in FIGS. 4A to C to FIGS. 11A to C. Note that, FIG. 4A to FIG. 11A are examples schematically showing manufacturing phases of the cross-sectional structure corresponding to FIG. 3A, FIG. 4B to FIG. 11B are examples schematically showing manufacturing phases of the cross-sectional structure corresponding to FIG. 3B, and FIG. 4C to FIG. 11C are examples schematically showing manufacturing phases of the cross-sectional structure corresponding to FIG. 3C.

As shown in FIGS. 4A to AC, a gate insulating film 7, for example, a silicon oxide film, is formed on the surface of a p-type silicon substrate 1 by well-known thermal oxidation. Thereafter, for example, a doped polycrystalline silicon layer 8 to be the floating gate electrode film FG is film-formed by low pressure chemical vapor deposition. Phosphorus (P), for example, is used as impurities of the doped polycrystalline silicon layer 8. The film thickness of the doped polycrystalline silicon layer 8 is approximately 10 nm, for example.

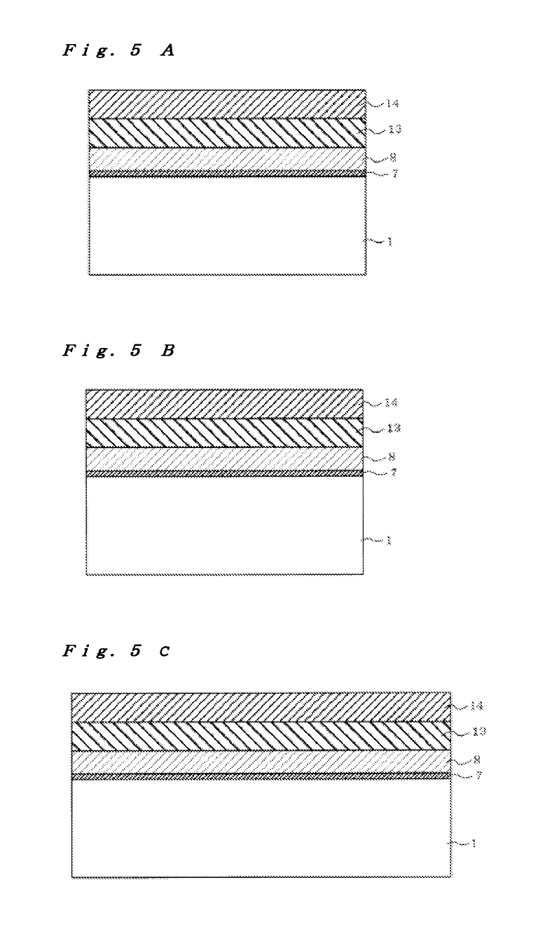

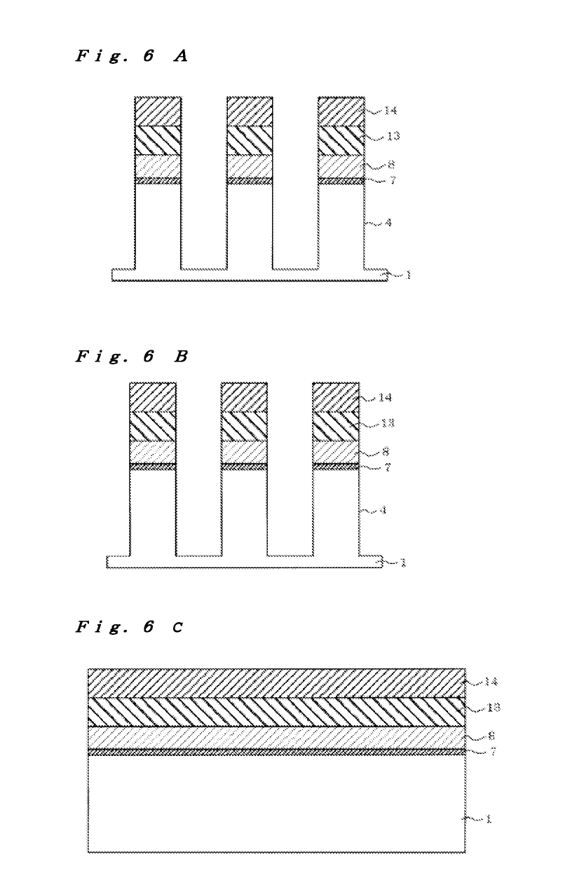

As shown in FIGS. 5A to 5C, a silicon nitride film 13 is formed on the doped polycrystalline silicon layer 8 by chemical vapor deposition. Subsequently, a silicon oxide film 14 is formed on the silicon nitride film 13 by chemical vapor deposition. Thereafter, a photoresist (not shown) is applied on the silicon oxide film 14, and the resist is patterned by exposure and development. Then, using the resist as a mask, the silicon oxide film 14 is etched by RIE (reactive ion etching). After the etching, the photoresist is removed, and the silicon nitride film 13 is etched using the silicon oxide film 14 as a mask. Subsequently, the polycrystalline silicon layer 8 (floating gate electrode film FG), the gate insulating film 7, and the silicon substrate 1 are etched. As a result, the element isolation grooves 4 are formed (see FIGS. 6A and 6B).

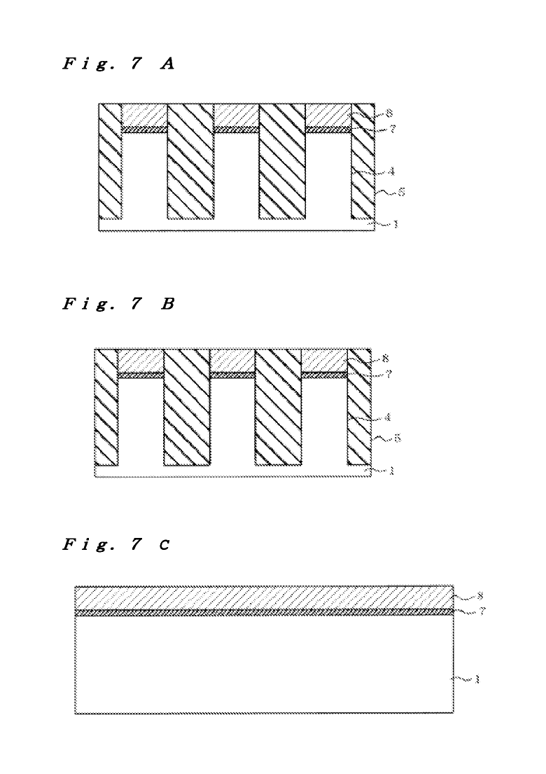

Thereafter, using the chemical vapor deposition or the technique of application, a silicon oxide film 5, for example, is embedded in the processed grooves 4. Then, as shown in FIGS. 7A to C, planarization is performed by CMP (Chemical Mechanical Polishing) to expose the polycrystalline silicon layer 8. As a result, the element isolation insulating film 5 is formed.

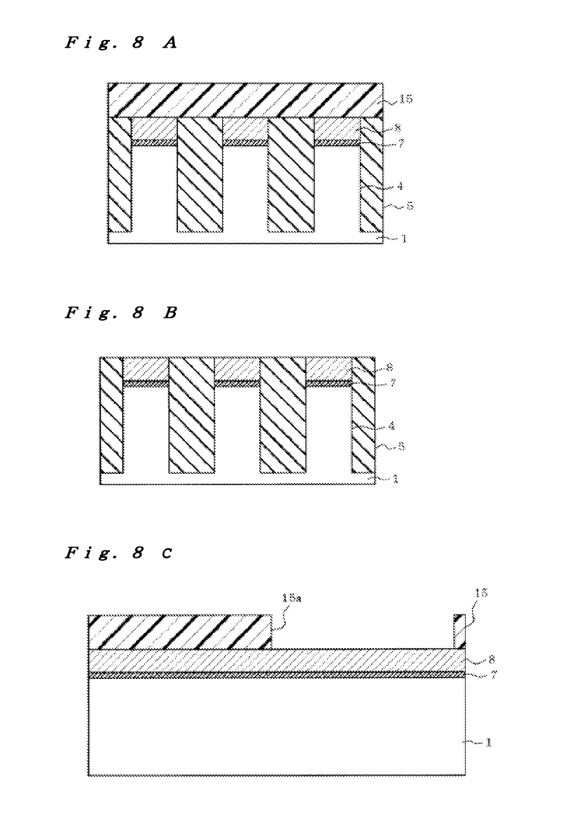

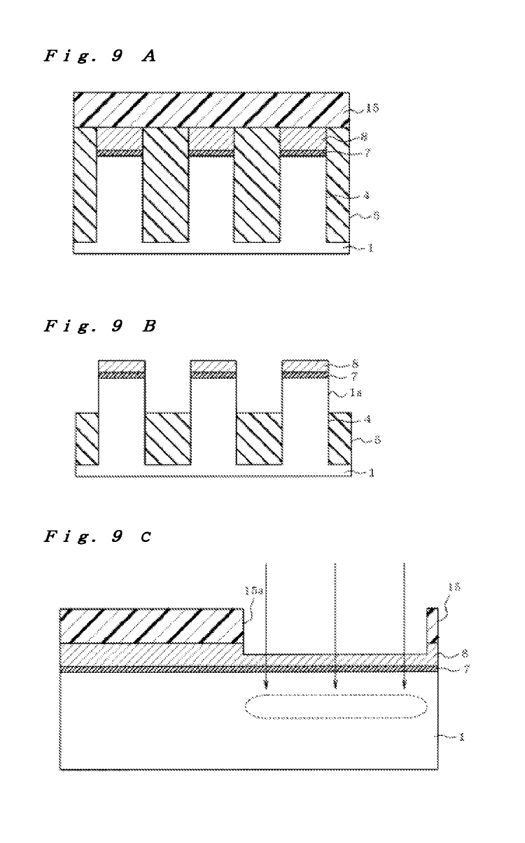

As shown in FIGS. 8A to C, a resist 15 is formed on the element isolation insulating film 5 and the polycrystalline silicon layer 8, and is exposed and developed to form an opening portion 15a (see FIGS. 8B and C) in the resist 15 in the formation region of the select gate transistor. As shown in FIGS. 9A to C, in the formation region of the select gate transistor, the element isolation insulating film 5 of the STI 2 is etched back such that the sidewall 1a of the silicon substrate 1 is exposed. In this case, as shown in FIGS. 9B and C, for the gate electrode SG of the select gate transistor, etching is performed so that the upper surface of the floating gate electrode film FG (polycrystalline silicon layer 8) is slightly shaved. Then, if necessary, impurities such as phosphorus are doped on the upper surface portion of the silicon substrate 1 through the opening portion 15a by ion implantation for controlling a threshold value of the select gate transistor (see arrows in FIG. 9C).

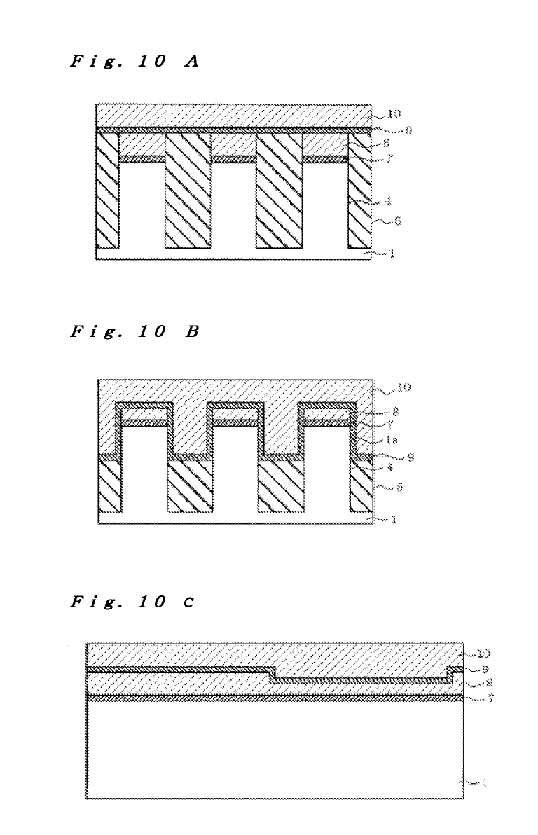

After removing the resist 15, as shown in FIG. 10A to C, the inter-electrode insulating film 9 is formed. In this process, in the formation region of the memory cell transistor, the inter-electrode insulating film 9 is formed along the upper surface of the element isolation insulating film 5 and the upper surface of the floating gate electrode film FG (see FIG. 10A). In addition, in the formation region of the select gate transistor, the inter-electrode insulating film 9 is formed along the upper surface of the element isolation insulating film 5, the sidewall 1a of the silicon substrate 1, the side surfaces of the gate insulating film 7, and the side surfaces and the upper surface of the floating gate electrode film FG (see FIG. 10B). As for the inter-electrode insulating film 9, a film having a stacked structure of silicon oxide film/silicon nitride film/silicon oxide film, what is called an ONO film, is formed by the well-known process. Note that, a high-dielectric constant insulating film of a simple substance, a film having a stacked structure of silicon oxide film/high-dielectric constant insulating film/silicon oxide film, or a film having a stacked structure of silicon nitride film/silicon oxide film/silicon nitride film/silicon oxide film/silicon nitride film (NONON film) may be formed as the inter-electrode insulating film 9.

A doped polycrystalline silicon layer to be the conductive layer 10 (control gate electrode film CG) is formed on the inter-electrode insulating film 9 by chemical vapor deposition. Note that, phosphorus (P), for example, is used as impurities of the doped polycrystalline silicon layer 10.

The electrode isolation grooves 11 are formed to form the gate electrodes MG of the memory cell transistors, the gate electrodes SG of the select gate transistors, other gate electrodes, and the like in a separating manner (see FIG. 11C). This process is called as gate processing.

Impurities are doped on the surface of silicon substrate 1 at the inner bottom portion of the groove 11 by ion implantation to form source/drain regions. An inter-memory cell insulating film 12 as an inter-cell gate insulating film is formed in the groove 11 (see FIG. 3C). Further, a nickel silicide (NiSi) layer is formed on the upper portion of the polycrystalline silicon layer (conductive layer) 10. Thereafter, a chip of the NAND type flash memory device is formed followed by the processes including formation of a contact and formation of a wiring layer.

According to the embodiment of such a configuration, in the formation region of the select gate transistor, the inter-electrode insulating film 9 is formed along the upper surface of the element isolation insulating film 5, the sidewall 1a of the silicon substrate 1, the side surfaces of the gate insulating film 7, and the side surfaces and the upper surface of the floating gate electrode film FG. As a result, the inter-electrode insulating film 9 functions as a gate insulating film of a select gate transistor, thereby making it possible to easily control a threshold value of the select gate transistor. Moreover, in the embodiment, the formation region of the select gate transistor is configured such that the gate insulating film (tunnel insulating film) 7 and the floating gate electrode film FG are stacked on the upper surface of the silicon substrate 1, and the side surfaces of the gate insulating film 7 as well as the side surfaces and the upper surface of the floating gate electrode film FG are covered by the inter-electrode insulating film 9. As a result, electrons trapped in the floating gate electrode film FG raise the threshold value of the select gate transistor. Accordingly, the off-leak current when the gate voltage of the select gate transistor is 0V (cutoff) can be reduced.

### Second Embodiment

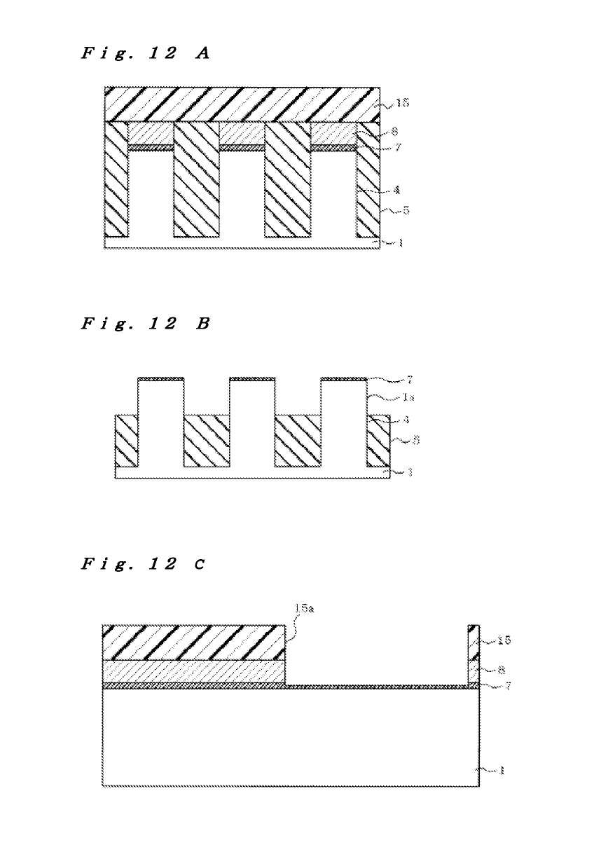

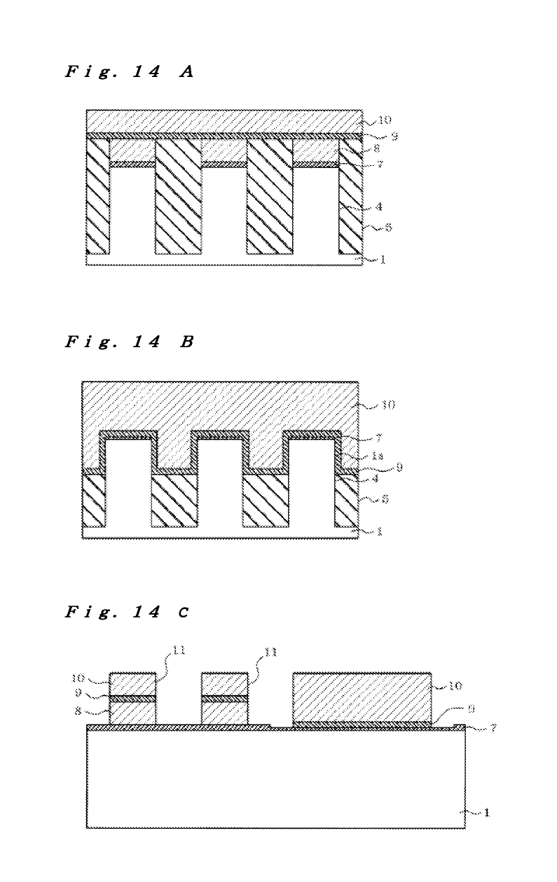

FIGS. 12A to C to FIGS. 14A to C are examples showing a second embodiment. Note that, the same portions as those of the first embodiment are denoted with the same reference numerals. The second embodiment is configured such that the floating gate electrode film FG (polycrystalline silicon layer 8) which traps electrons the gate electrode SG of the select gate transistor is not left.

Specifically, the phases in from FIGS. 4A to C to FIGS. 8A to C in the manufacturing process of the first embodiment are similarly executed in the second embodiment. Thereafter, in the second embodiment, as shown in FIG. 12B, the element isolation insulating film 5 of the STI 2 is etched back such that the sidewall 1a of the silicon substrate 1 is exposed. In this process, as shown in FIG. 12C, the gate electrode SG of the select gate transistor is etched to expose the gate insulating film 7. In other words, etching is performed such that the floating gate electrode film FG (polycrystalline silicon layer 8) is removed to slightly shave the upper surface of the gate insulating film 7. Then, if necessary, impurities such as phosphorus are doped on the upper surface portion of the silicon substrate 1 through the opening portion 15a by ion implantation for controlling a threshold value of the select gate transistor.

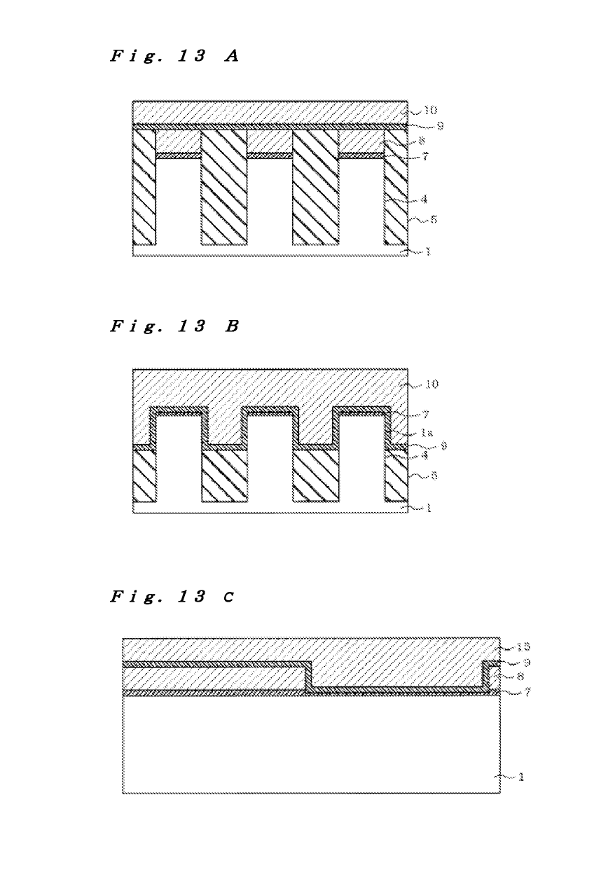

After removing the resist 15, as shown in FIGS. 13A to C, the inter-electrode insulating film 9 is formed. In this case, in the formation region of the memory cell transistor, the inter-electrode insulating film 9 is formed along the upper surface of the element isolation insulating film 5 and the upper surface of the floating gate electrode film FG (polycrystalline silicon layer 8) (see FIG. 13A). In addition, in the formation region of the select gate transistor, the inter-electrode insulating film 9 is formed along the upper surface of the element isolation insulating film 5, the sidewall 1a of the silicon substrate 1, the side surfaces and the upper surface of the gate insulating film 7 (see FIG. 13B). A doped polycrystalline silicon layer to be the conductive layer 10 (control gate electrode film CG) is formed on the inter-electrode insulating film 9 by chemical vapor deposition.

Next, the gate processing is performed, in other words, the electrode isolation grooves 11 are formed to form the gate electrodes MG of the memory cell transistors, the gate electrodes SG of the select gate transistors, other gate electrodes, and the like in a separating manner (see FIG. 14C).

Note that, the configuration of the second embodiment except the configuration described above is the same as the configuration of the first embodiment. Accordingly, also in the second embodiment, the threshold value of the select gate transistor can be easily controlled.

### Third Embodiment

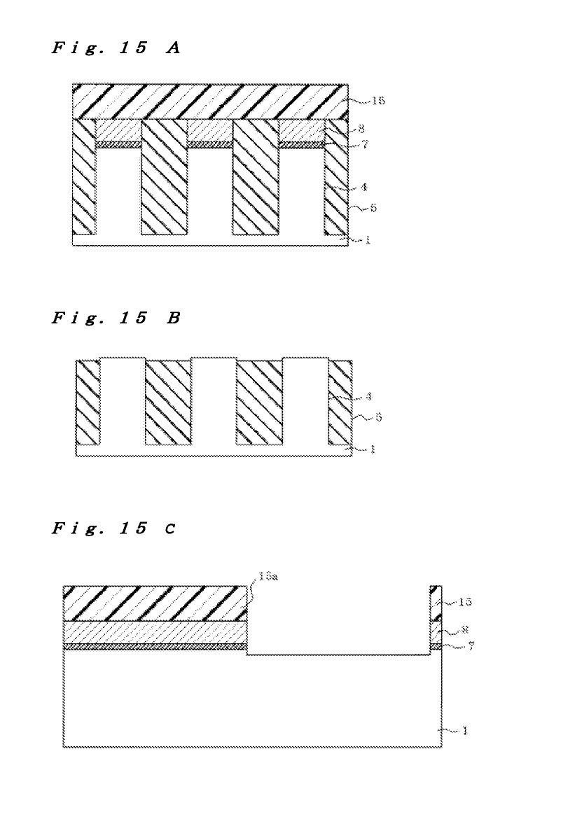

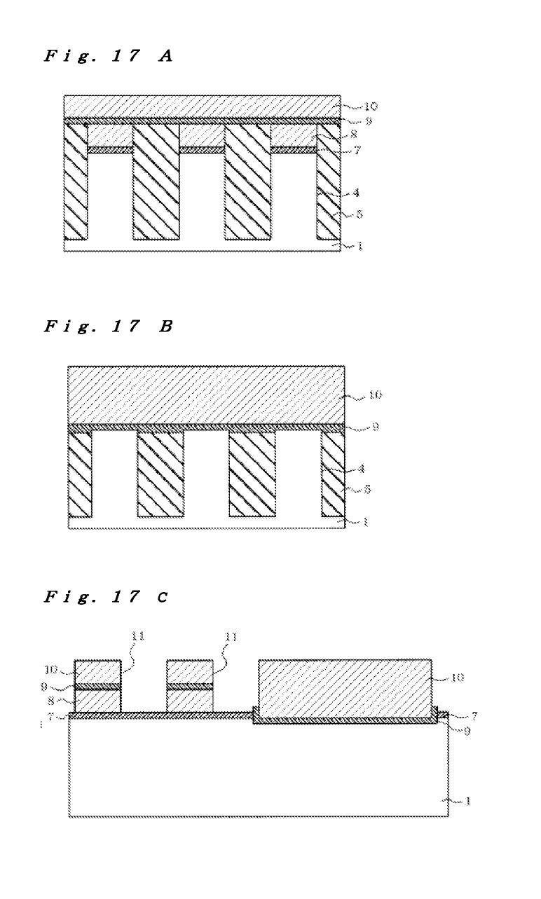

FIGS. 15A to C to FIGS. 17A to C are examples showing a third embodiment. Note that, the same portions as those of the first embodiment are denoted with the same reference numerals. The third embodiment is configured such that, for the gate electrode SG of the select gate transistor, the floating gate electrode film FG (polycrystalline silicon layer 8) and the gate insulating film 7 are removed to make the inter-electrode insulating film 9 function as a gate insulating film.

Specifically, the phases in from FIGS. 4A to C to FIGS. 8A to C in the manufacturing process of the first embodiment are similarly executed in the third embodiment. Thereafter, in the third embodiment, as shown in FIGS. 15B and C, the element isolation insulating film 5 of the STI 2 is etched back such that the upper surface of the silicon substrate 1 is exposed. In this process, as shown in FIGS. 15B and C, for the gate electrode SG of the select gate transistor, etching is performed to expose the silicon substrate 1. In other words, etching is performed such that the floating gate electrode film FG (polycrystalline silicon layer 8) and the gate insulating film 7 are removed to slightly shave the upper surface of the silicon substrate 1. As a result, the upper surface of the silicon substrate 1 in the formation region of the select gate transistor is lower than the upper surface of the silicon substrate in the formation region of the memory cell transistor. Then, if necessary, impurities such as phosphorus are doped on the upper surface portion of the silicon substrate 1 through the opening portion 15a by ion implantation for controlling a threshold value of the select gate transistor.

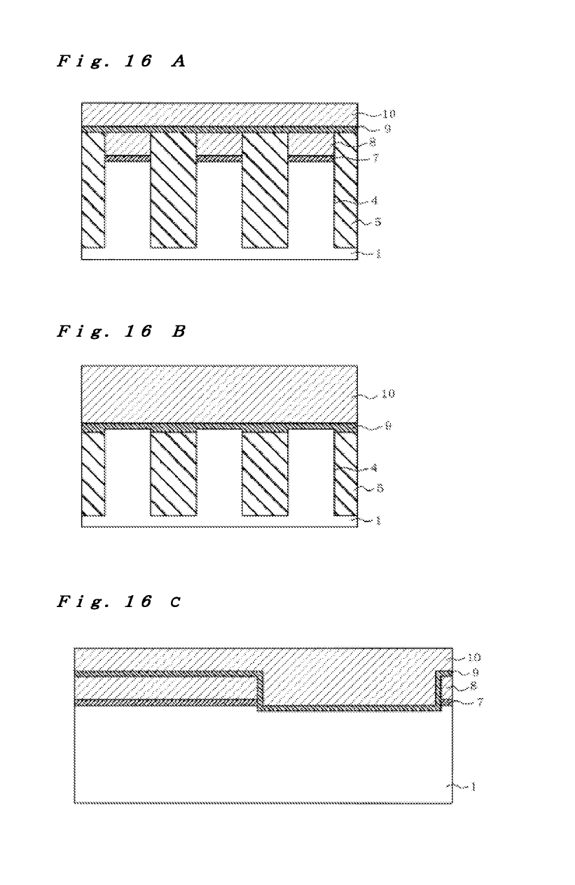

After removing the resist 15, as shown in FIGS. 16A to C, the inter-electrode insulating film 9 is formed. In this process, in the formation region of the memory cell transistor, the inter-electrode insulating film 9 is formed along the upper surface of the element isolation insulating film 5 and the upper surface of the floating gate electrode film FG (polycrystalline silicon layer 8). In addition, in the formation region of the select gate transistor, the inter-electrode insulating film 9 is formed along the upper surface of the element isolation insulating film 5 and the upper surface of the silicon substrate 1. Subsequently, a doped polycrystalline silicon layer to be the conductive layer 10 (control gate electrode film CG) is formed on the inter-electrode insulating film 9 by chemical vapor deposition.

The gate processing is performed, in other words, the electrode isolation grooves 11 are formed to form the gate electrodes MG of the memory cell transistors, the gate electrodes SG of the select gate transistors, other gate electrodes, and the like in a separating manner (see FIG. 17C).

Note that, the configuration of the third embodiment except the configuration described above is the same as the configuration of the first embodiment. Accordingly, also in the third embodiment, the threshold value of the select gate transistor can be easily controlled. In particular, the third embodiment is configured such that, in the formation region of the select gate transistor, the floating gate electrode film FG (polycrystalline silicon layer 8) and the gate insulating film 7 on the upper surface of the silicon substrate 1 are removed and the inter-electrode insulating film 9 formed on the upper surface of the silicon substrate 1 are made function as a gate insulating film. As a result, the threshold value of the select gate transistor can be easily controlled.

### Fourth Embodiment

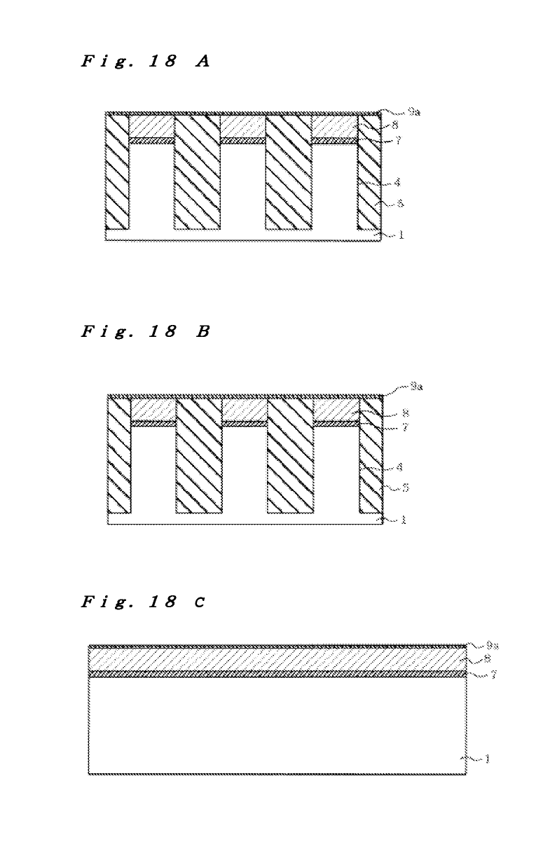

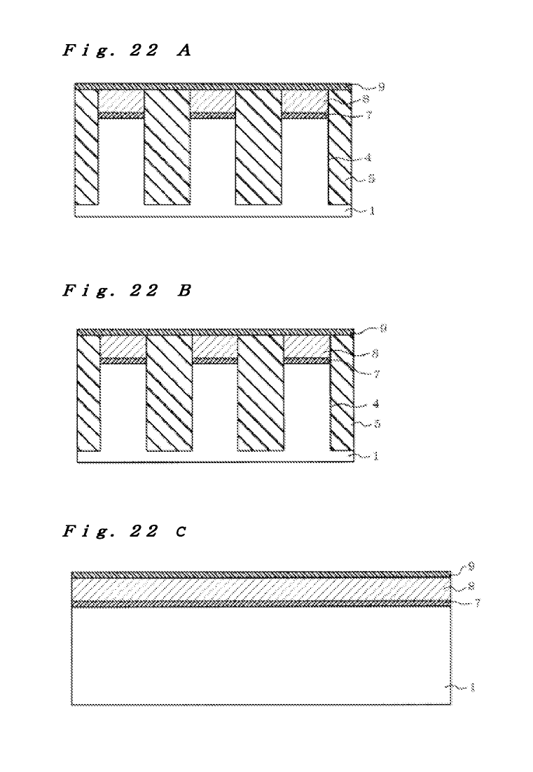

FIGS. 18A to C to FIGS. 22A to C are examples showing a fourth embodiment. Note that, the same portions as those of the first embodiment are denoted with the same reference numerals. The fourth embodiment is configured such that the inter-electrode insulating film 9 is made of the NONON film, and a part of the inter-electrode insulating film 9 (NON film) is formed before the element isolation insulating film 5 is etched back, whereas the remaining part of the inter-electrode insulating film 9 (ON film) is formed after the element isolation insulating film 5 is etched back.

Specifically, the phases in from FIGS. 4A to C to FIGS. 8A to C in the manufacturing process of the first embodiment are similarly executed in the fourth embodiment. Thereafter, in the fourth embodiment, as shown in FIGS. 18A to C, an (NON film) 9a, which is a part of the inter-electrode insulating film (NONON film) 9, is formed on the element isolation insulating film 5 and the floating gate electrode film FG (polycrystalline silicon layer 8). The film thickness of the (NON film) 9a, which is a part of the inter-electrode insulating film (NONON film) 9, is approximately 10 nm, for example.

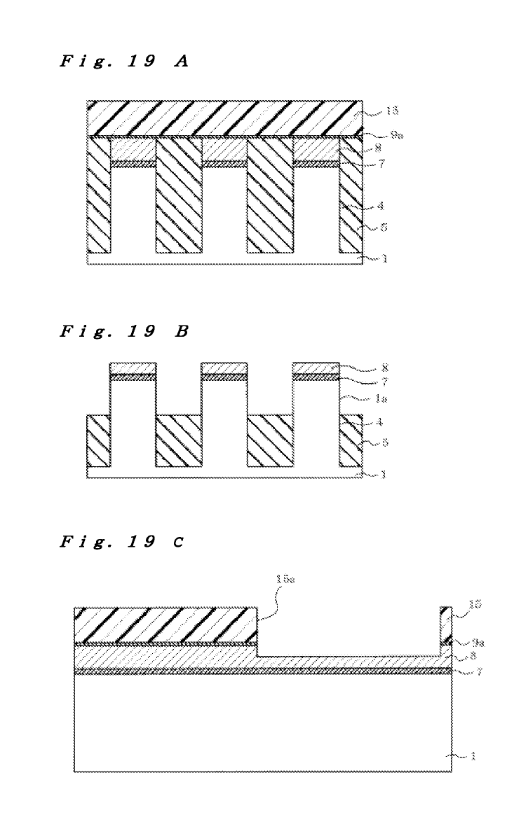

As shown in FIGS. 19A to C, the resist 15 is formed on this part (NON film) of the inter-electrode insulating film 9, and is exposed and developed to form the opening portion 15a in the resist 15 in the formation region of the select gate transistor. Further, the element isolation insulating film 5 of the STI 2 is etched back such that the sidewall 1a of the silicon substrate 1 is exposed. In this case, as shown in FIGS. 19A to C, for the gate electrode SG of the select gate transistor, etching is performed to expose, in other words, to slightly shave the upper surface of the floating gate electrode film FG (polycrystalline silicon layer 8). Then, if necessary, impurities such as phosphorus are doped on the upper surface portion of the silicon substrate 1 through the opening portion 15a by ion implantation for controlling a threshold value of the select gate transistor.

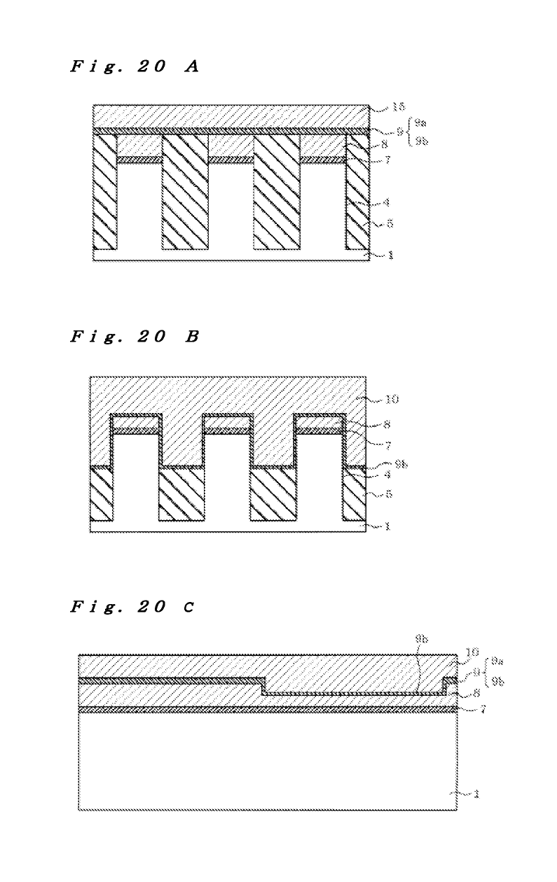

After removing the resist 15, as shown in FIGS. 20A to C, the remaining part (ON film) 9b of the inter-electrode insulating film 9 is formed. The film thickness of the remaining part (ON film) 9b of the inter-electrode insulating film 9 is approximately 5 nm, for example. In this case, in the formation region of the memory cell transistor, the remaining part (ON film) 9b of the inter-electrode insulating film 9 is formed along the upper surface of a part (NON film) 9a of the inter-electrode insulating film 9 (see FIGS. 20A and C). In addition, in the formation region of the select gate transistor, the remaining part (ON film) 9b of the inter-electrode insulating film 9 is formed along the upper surface of the element isolation insulating film 5, the sidewall 1a of the silicon substrate 1, the side surfaces of the gate insulating film 7, the side surfaces and the upper surface of the floating gate electrode film FG (polycrystalline silicon layer 8) (see FIGS. 20B and C). A doped polycrystalline silicon layer to be the conductive layer 10 (control gate electrode film CG) is formed on the inter-electrode insulating film 9 by chemical vapor deposition.

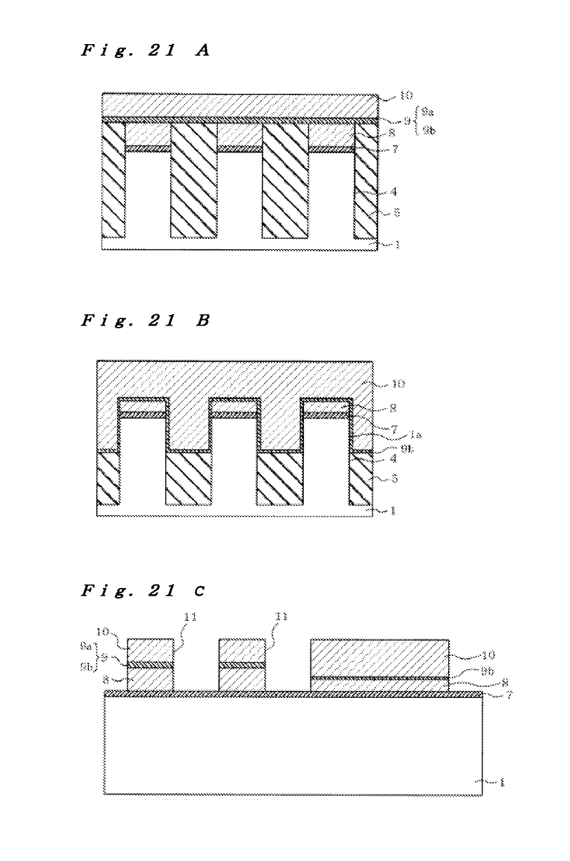

The electrode isolation grooves 11 are formed to form the gate electrodes MG of the memory cell transistors, the gate electrodes SG of the select gate transistors, other gate electrodes, and the like in a separating manner (see FIG. 21C).

Note that, the configuration of the fourth embodiment except the configuration described above is the same as the configuration of the first embodiment. Accordingly, also in the fourth embodiment, the functional effects similar to those of the first embodiment can be obtained. In particular, the fourth embodiment is configured such that the inter-electrode insulating film 9 is film-formed through separate two steps, thereby making it possible to achieve the thinner film thickness of the gate insulating film 9b which is formed on the sidewall 1a of the silicon substrate 1. Accordingly, the threshold value of the select gate transistor can be easily controlled.

### Fifth Embodiment

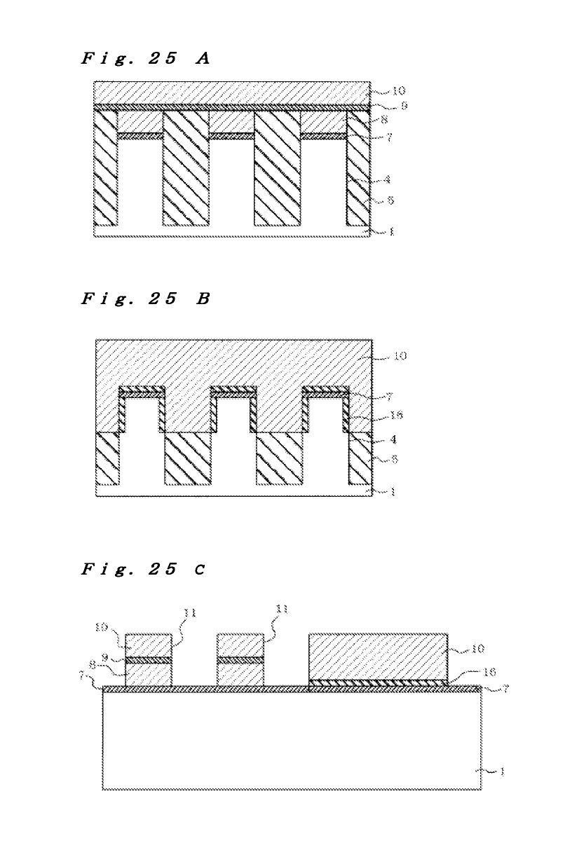

FIGS. 22A to C to FIGS. 25A to C are examples showing a fifth embodiment. Note that, the same portions as those of the first embodiment are denoted with the same reference numerals. The fifth embodiment is configured such that a gate insulating film of the select gate transistor is formed by oxidation of the silicon substrate 1, without using the inter-electrode insulating film 9.

Specifically, the phases in from FIGS. 4A to C to FIGS. 8A to C in the manufacturing process of the first embodiment is similarly executed in the fifth embodiment. Thereafter, in the fifth embodiment, as shown in FIGS. 22A to C, the inter-electrode insulating film 9 is formed on the element isolation insulating film 5 and the floating gate electrode film FG (polycrystalline silicon layer 8).

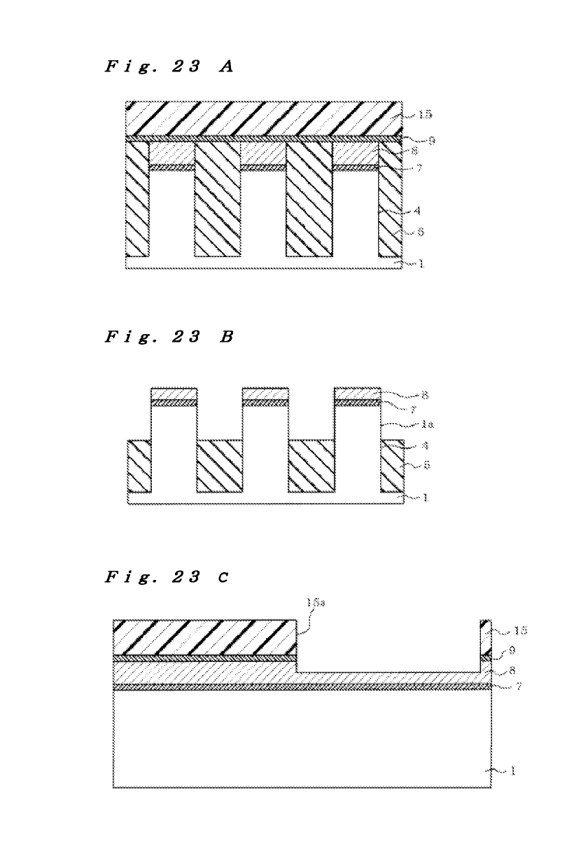

As shown in FIGS. 23A to C, the resist 15 is formed on the inter-electrode insulating film 9, and is exposed and developed to form the opening portion 15a in the resist 15 in the formation region of the select gate transistor. Further, the element isolation insulating film 5 of the STI 2 is etched back such that the sidewall 1a of the silicon substrate 1 is exposed. In this process, as shown in FIG. 23C, for the gate electrode SG of the select gate transistor, etching is performed to expose the floating gate electrode film FG (polycrystalline silicon layer 8). In other words, etching is performed such that the upper surface of the floating gate electrode film FG (polycrystalline silicon layer 8) is slightly shaved. Then, if necessary, impurities such as phosphorus are doped on the upper surface portion of the silicon substrate 1 through the opening portion 15a by ion implantation for controlling a threshold value of the select gate transistor.

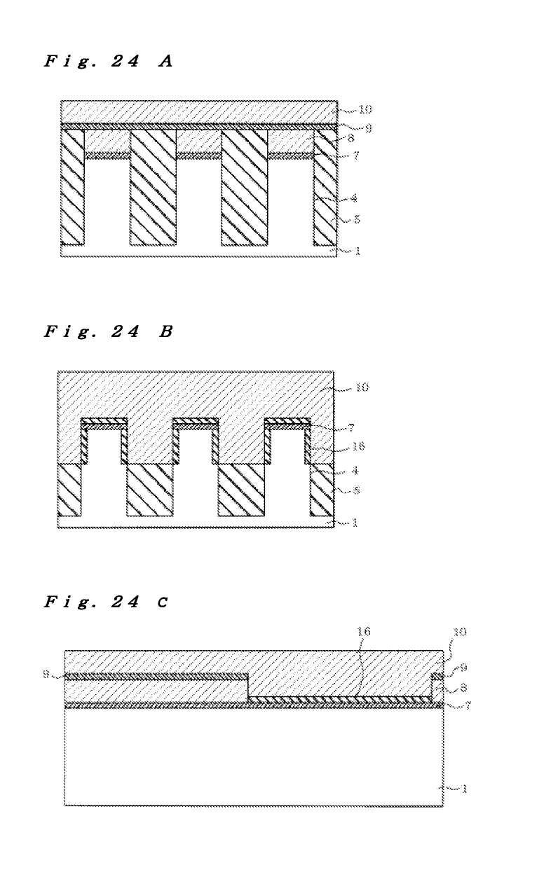

Next, for the gate electrode SG of the select gate transistor, the sidewall 1a of the silicon substrate 1 and the floating gate electrode film FG (polycrystalline silicon layer 8) are oxidized by SPA (Slot Plant Antenna) oxidation to form a silicon oxide film 16 (see FIG. 24B). In this process, the material of the inter-electrode insulating film 9 may be different from the material of the silicon oxide film 16. Moreover, the film thickness of the inter-electrode insulating film 9 may be different from the film thickness of the silicon oxide film 16. At this time, an element region of the semiconductor substrate for the select gate transistor is convex shape.

After removing the resist 15, as shown in FIGS. 24A to C, a doped polycrystalline silicon layer to be the conductive layer 10 (control gate electrode film CG) is formed on the inter-electrode insulating film 9 and the silicon oxide film 16 by chemical vapor deposition. The gate processing is performed, in other words, the electrode isolation grooves 11 are formed to form the gate electrodes MG of the memory cell transistors, the gate electrodes SG of the select gate transistors, other gate electrodes, and the like in a separating manner (see FIG. 25C).

Note that, the configuration of the fifth embodiment except the configuration described above is the same as the configuration of the first embodiment. Accordingly, also in the fifth embodiment, the threshold value of the select gate transistor can be easily controlled. In particular, according to the fifth embodiment, the gate insulating film (silicon oxide film 16) of the select gate transistor is formed by oxidation of the silicon substrate 1, without using the inter-electrode insulating film 9. As a result, the size of the silicon substrate 1 (element region 3) of the select gate transistor can be configured to have a size in the gate width direction narrower than that of the first embodiment and other embodiments. Accordingly, embeddability of the control gate electrode film CG (polycrystalline silicon layer 10) can be improved. Moreover, the fifth embodiment is configured such that the silicon substrate 1 is oxidized by SPA oxidation. Accordingly, the reforming effects of the inter-electrode insulating film 9 can be obtained with the SPA oxidation.

### Other Embodiments

The following configuration may be employed in addition to the plurality of embodiments described above.

In the fourth embodiment, the inter-electrode insulating film (NONON film) 9 is configured to be separately film-formed into the NON film 9a and the ON film 9b. However, the configuration is not limited to the above case. An inter-electrode insulating film having another stacked structure may be film-formed into separate two films, as appropriate. Furthermore, in the fifth embodiment, the silicon substrate 1 is configured to be oxidized by SPA oxidation. However, the configuration is not limited to the above case. The silicon substrate 1 is oxidized by another oxidation method.

As described above, the semiconductor device according to the embodiments is provided with the gate structure of the flat cell structure, and the threshold value of the select gate transistor can be easily controlled while the select gate transistor is not required to be separately formed.

Although the several embodiments of the invention were explained, these embodiments are merely provided as examples and do not aim to limit the scope of the invention. These novel embodiments can be executed in other various forms, and various omissions, substitutions, and changes can be made hereto without departing from the spirit of the invention. These embodiments and modifications thereof are included in the scope and the spirit of the invention, and included in the scope of the invention described in claims and the range equivalent thereto.

What is claimed is:

1. A semiconductor device, comprising:
a semiconductor substrate;
a pair of select gate transistors provided on a first region of the semiconductor substrate;
a plurality of memory cell transistors provided on a second region provided between the pair of select gate transistors on the semiconductor substrate;
a gate electrode of each of the memory cell transistors, the gate electrode provided on the second region via a first insulating film, and including a charge storage layer, an intermediate insulating film, and a control gate electrode film stacked therein;
a groove exposed a sidewall of the semiconductor substrate on the first region; and
a gate electrode of each of the select gate transistors, the gate electrode including the control gate electrode film formed on the sidewall via a second insulating film.

2. The semiconductor device according to claim 1, wherein, in the first region, a lower surface of the second insulating film is positioned lower than an upper surface of the semiconductor substrate.

3. The semiconductor device according to claim 1, wherein an element region of the semiconductor substrate for the select gate transistor in the first region is convex shape.

4. The semiconductor device according to claim 1, wherein a third insulating film is formed on an upper surface of the semiconductor substrate in the first region.

5. The semiconductor device according to claim 4, wherein an electrode made of the same material as the charge storage layer is provided on the third insulating film.

6. The semiconductor device according to claim 5, wherein an upper surface and a side surface of the electrode are covered by the second insulating film.

7. The semiconductor device according to claim 4, wherein the third insulating film is provided between the semiconductor substrate and the second insulating film, and the third insulating film is indirect contact with the second insulating film.

8. The semiconductor device according to claim 1, wherein an upper surface of the semiconductor substrate in the first region is positioned lower than an upper surface of the semiconductor substrate in the second region.

9. The semiconductor device according to claim 8, wherein the second insulating film is in direct contact with the upper surface of the semiconductor substrate in the first region.

10. The semiconductor device according to claim 1, wherein a thickness of the second insulating film is thinner than a thickness of the intermediate insulating film.

11. The semiconductor device according to claim 7, wherein a thickness of the second insulating film is thinner than a thickness of the intermediate insulating film.

12. The semiconductor device according to claim 1, wherein a material of the intermediate insulating film is different from a material of the second insulating film.

13. The semiconductor device according to claim 1, wherein a material of the intermediate insulating film is the same as a material of the second insulating film.

14. The semiconductor device according to claim 5, wherein a thickness of the electrode is thinner than a thickness of the charge storage layer.

15. A method of manufacturing a semiconductor device, the method comprising the steps of:
forming a first insulating film on a semiconductor substrate;
forming a charge storage layer on the first insulating film;
forming an element isolation groove by processing the charge storage layer, the first insulating film, and the semiconductor substrate;
embedding an element isolation insulating film into the element isolation groove and planarizing the element isolation insulating film;
exposing a sidewall of the semiconductor substrate by etching back the semiconductor substrate in a formation region of a select gate transistor while the element isolation insulating film and the charge storage layer in a formation region of a memory cell transistor are masked;
doping impurities into an upper surface portion of the semiconductor substrate in the formation region of the select gate transistor;
forming an insulating film on the sidewall of the semiconductor substrate;
forming a control gate electrode film on the insulating film; and
processing a gate electrode of the select gate transistor and a gate electrode of the memory cell transistor.

16. The method of manufacturing a semiconductor device according to claim 15, wherein the insulating film is also formed on an upper surface of the element isolation insulating film when the insulating film is formed on the sidewall of the semiconductor substrate.

17. The method of manufacturing a semiconductor device according to claim 15, wherein in the step of exposing the sidewall of the semiconductor substrate, the charge storage layer and the first insulating film in the formation region of the select gate transistor are removed.
